(19) United States
(12) Patent Application Publication
(10) Pub. No.: US 2009/0289646 A1
(43) Pub. Date: Nov. 26, 2009

(54) TEST PROBE

(75) Inventors: Been-long Chen, Hsin-Chu City (TW); Huang-chih Chen, Hsin-Chu City (TW)

Correspondence Address: KIRTON AND MCCONKIE, 60 EAST SOUTH TEMPLE,, SUITE 1800, SALT LAKE CITY, UT, 84111, US

(73) Assignee: IPWORKS TECHNOLOGY CORP., Hsin-Chu (TW)

(21) Appl. No.: 12/358,457

(22) Filed: Jan. 23, 2009

(30) Foreign Application Priority Data
May 20, 2008 (TW) 097118543

(51) Int. Cl. G01R 31/02; G01R 1/067

(52) U.S. Cl. 324/754

(57) ABSTRACT

A test probe pin is disclosed. The test probe has a plurality of probes, each of which has a probe tip surface coated with a nano-film of conducting polymer, and the thickness of the nano-film is about 1-20 nm. The probes coated with the nano-film are installed on a test fixture for testing IC components, so that the probes can efficiently provide excellent no-clean property and stabler electro-conductivity for lowering the cleaning frequency of the probes, enhancing the yield of IC component testing, increasing the utility rate of the test fixture, reducing the total testing cost, elongating the usage lifetime of the test probe, and reducing the cost of probe material. Thus, due to the nano-film of conducting polymer, the probes made of metal material can provide almost the same electro-conductivity as a traditional probe by only plating a gold layer of one fifth of original thickness, so that the cost of whole probe material can be reduced.

### FIELD OF THE INVENTION

The present invention relates to a test probe of a test fixture for integrated circuit (IC) components probing, and more particularly to a test probe coated with a nano-film of conducting polymer material.

### BACKGROUND OF THE INVENTION

Traditional test probes applied to a test fixture are mainly made of beryllium-copper (Be—Cu) alloy and has a surface coated with a gold (Au) layer. The size and shape of the test probes may be varied according to-be-tested integrated circuit (IC) components, but the basic structure thereof is the same and comprises probe pins, sleeves, and springs. The test probes of the test fixture can be applied to various fields, such as test probes for printed circuit board (bare board and finished board), test probes for semiconductor test, test probes for display panel, and test probes for components of telecommunication products including various connectors for antennae of mobile phones, batteries, loudspeakers, vibrators, LCD panels, and even connectors for other products, such as personal digital assistant (PDA), digital camera, global position system (GPS), and notebooks. Furthermore, for the field of wafer probing, the test probes are one part of a probe card. Before the integrated circuit (IC) components are packaged, the test probes can be used to test electrical functions of dies (i.e. chips) cut from a wafer, in order to remove defective dies and keep known good dies for the following packaging processes. Thus, a wafer probing test is one of important processes in the integrated circuit fabrication, which affects the manufacture cost thereof.

During manufacturing the test probes of the test fixture, the quality and test performance of the whole test probes may be affected by probe design, material selection, finishing precision control, and assembling operation of the test probes. Hence, in order to increase the electro-conductivity of the test probes, the Be—Cu surface of the test probes will be coated with a gold (Au) layer which has a thickness about 2-100 micrometer (μm) varied according to customer's needs and to-be-tested products.

When the test probes are used, the test probes must be fixed on the test fixture. However, the fixing operation may cost much labor power and time, and can not be carried out by a batch fabrication manner, so that the manufacture cost of the test fixture can not be efficiently lowered. For example, in a step of fixing the test probes by the test fixture, the test probes only can be manually fixed on a printed circuit board one by one according to the design of the test fixture after confirming locations of pads on the printed circuit board. Finally, one end of each of the test probes will be electrically connected to each of the pads on the printed circuit board, and the other exposed end of each of the test probes can be used to be in contact with each of pads on a to-be-tested chip or other integrated circuit (IC) components for electrical test. The foregoing complicated processes cause that the usage lifetime of the test probes on the test fixture becomes one of factors affecting the manufacture cost of the test fixture.

Besides, when the number of the test probes is increased, the co-planarity of the test probes will be inevitably lowered, so as to limit the size of the whole test probes of the test fixture. In other words, it is difficult to maintain sufficient yield and stability if a plurality of to-be-tested dies or integrated circuit (IC) components are simultaneously tested.

Furthermore, for providing better test quality by finely contacting the whole test probes of the test fixture with the to-be-tested dies, the probe tip of the test probes may penetrate into pad surface of the to-be-tested dies or integrated circuit (IC) components to satisfy the fine contact purpose. However, after the test probes are repeatedly penetrated into the pad surface of several to-be-tested dies, the probe tip of the test probes may be easily wetted with solder, resulting in deteriorating the test quality or causing erroneous test. As a result, the test yield may be rapidly lowered. Generally, to solve the foregoing problem, an overdrive contact force may be used to force the probe tip to deeply penetrate into the pad surface of the to-be-tested dies, so that the contact condition and the test quality can be enhanced and improved. Although the overdrive contact force can be used to solve the foregoing problem and enhance the test yield, the overdrive contact force may damage other lower structure under the pad surface of the to-be-tested dies. Especially, when current technologies of advanced wafer processes (such as 0.13 μm, 90 nm, 65 nm, and etc.) are generally carried out on wafers made of fragile low-k dielectric material, the low-k dielectric material may be a barrier for the wafer probing test using the overdrive contact force to solve the foregoing problem and the following packaging processes thereof. When the low-k dielectric material or ultra-low-k dielectric material is applied to IC processes less than 0.13 μm, the wafer probing test must be controlled to prevent the low-k dielectric material and other lower material or structure thereof from being deformed or damaged. Moreover, a cleaning method of the test probes can be used to solve the foregoing problem. However, once the number of the test probes is increased or the pitch between the adjacent test probes is decreased, the cleaning frequency of the test probes may be considerably increased, resulting in lowering the utility rate of test machines and shortening the lifetime of the test probes.

To increase the electro-conductivity of the test probes, the Be—Cu surface of the test probes will be coated with a gold (Au) layer which generally has a thickness about 2-100 μm, resulting in increasing the whole cost of the test probes. In addition, there is a wetting problem generally existing in the test probes. Especially, when a leadless solder process is used, the wetting problem will be worse than that of traditional lead-containing solder process. Furthermore, when the test is carried out under high temperature, the wetting problem will be worse than that of the test under room temperature.

Recently, although related manufacturers develop a kind of test probe having a surface coated with a metal film to elongate the lifetime of the test probe, the wetted problem still cannot be solved. Moreover, the metal film cannot maintain identical resistance value when the test probe is used to test. As a result, the metal film still cannot enhance the test yield and the test stability.

### SUMMARY OF THE INVENTION

A primary object of the present invention is to provide a test probe, which can stabilize the test quality of wafer probing test, and prevent the probe tip of the test probe from being wetted with a to-be-tested die, so as to lower the cleaning frequency of the test probe, increase the utility rate of test machines, and increase the test yield of the die for the purpose of reducing the entire test cost. The test probe of the present invention is coated with a nano-film of conducting polymer, so that the test probe made of Be—Cu alloy can provide the same electro-conductivity as a traditional test probe by only plating a gold layer of one fifth of original thickness. Thus, the cost of whole probe material can be reduced.

To achieve the above object, the test probe of a preferred embodiment of the present invention comprises a plurality of probes which is made of metal material and installed on a test fixture, and a nano-film of conducting polymer coated on the probes.

According to the test probe in a preferred embodiment of the present invention, the nano-film of conducting polymer is preferably conducting polymer having a no-clean property, and the thickness of the nano-film is preferably about 1-20 nanometer (nm).

According to the test probe in the preferred embodiment of the present invention, the metal material of the probes can be preferably selected from the group consisting of nickel (Ni), gold (Au), copper (Cu), tungsten (W), rhenium (Re), titanium (Ti), beryllium (Be), stainless steel, other electro-conductive metal, and alloy thereof. Each of the probes has a surface selectively coated with a metal film before forming the nano-film. The operation mode of the probes can be selected from unidirectional motion or bi-directional motion. The structure of each of the probes can be preferably selected from a metal micro-spring, a metal pin, a single tip pin, or a dual tip pin.

According to the test probe in the preferred embodiment of the present invention, the nano-film of conducting polymer is preferably coated on each of the probes by an evaporated and chemical plating process. The nano-film of conducting polymer is preferably coated on a probe tip surface of each of the probes.

The present invention is related to a test probe which has a probe surface coated with a nano-film of conducting polymer, so that the test probe can efficiently provide better no-clean property, stabler electro-conductivity, lower contact force, and longer usage lifetime.

The present invention is related to a test probe which is used to stabilize the test quality, wherein the test probe is designed according to the principle of approximately no attraction between the test probe and a to-be-tested die (or an integrated circuit (IC) component), so as to provide better no-clean property. Thus, the present invention can lower the cleaning frequency of the test probe, increase the utility rate of test machines, increase the test yield of the die, and reduce the entire test cost.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic view of a test probe according to a preferred embodiment of the present invention; and

FIG. 2 is a partially enlarged view of a nano-film on a probe tip surface of the test probe on a test fixture, as shown in FIG. 1.

### DETAILED DESCRIPTION OF THE PREFERRED EMBODIMENTS

A preferred embodiment of the present invention provides a test probe which comprises a plurality of probes and a nano-film of conducting polymer, wherein the probes are made of metal material and installed on a test fixture, and the nano-film of conducting polymer is coated on the probes.

In the present invention, the nano-film of conducting polymer can be preferably selected from conducting polymer having a no-clean property. For example, the conducting polymer can be selected from the group consisting of polypyrrole, polyparaphenylene, polythiophene, polyaniline, combination thereof, and derivative thereof. The thickness of the nano-film of conducting polymer is preferably about 1-20 nanometer (nm), especially about 1-5 nm.

In the present invention, the probes are made of the metal material which can be preferably selected from the group consisting of nickel (Ni), gold (Au), copper (Cu), tungsten (W), rhenium (Re), titanium (Ti), beryllium (Be), stainless steel, other electro-conductive metal, and alloy thereof. The foregoing alloy can be preferably selected from rhenium-tungsten (Re—W) alloy or beryllium-copper (Be—Cu) alloy.

In the present invention, each of the probes has a surface selectively coated with a metal film made of gold (Au) or nickel (Ni) before forming the nano-film (i.e. the nano-film is formed on the metal film). The thickness of the metal film is preferably about 0.4-20 micrometer (em). Furthermore, the operation mode of the probes can be selected from unidirectional motion or bi-directional motion. The structure of each of the probes can be preferably selected from a metal micro-spring, a metal pin, a single tip pin, or a dual tip pin.

In the present invention, the nano-film of conducting polymer is preferably coated on each of the probes by an evaporated and chemical plating process. The nano-film of conducting polymer is preferably coated on a probe tip surface of the probe.

In the present invention, the test probe is a pin structure made of metal material, and has a surface coated with the metal film. For example, a probe made of Be—Cu alloy has a surface coated with a gold layer, wherein the thickness of the gold layer is about 0.4-20 μm. The operation mode of the probes can be selected from unidirectional motion or bi-directional motion. The principle of bi-directional-motion probes is that two tips of the probes can be compressed inward for an electrical test when the two tips thereof are in contact with a product and a test board, respectively. The principle of unidirectional-motion probes is that only one tip of the probes can be compressed inward for an electrical test when the tip thereof is in contact with the product. Generally, there is no apparent difference between the operations of the bi-directional-motion probes and the unidirectional-motion probes.

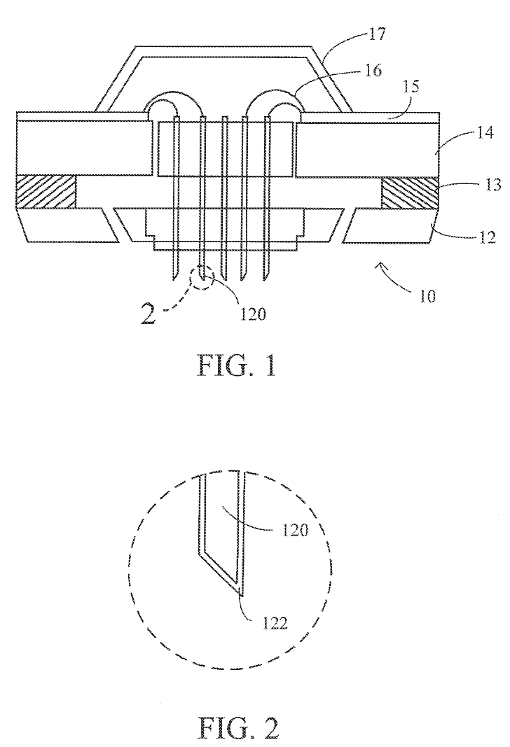

Referring now to FIG. 1, a schematic view of the test probe in the preferred embodiment of the present invention is illustrated. Generally, probes of a test fixture are a technology designed according to the test fixture, wherein dozens or hundreds of probes are mounted on a substrate. As shown in FIG. 1, a whole probe structure of a test fixture 10 comprises a probe board 12, a substrate 14, a ceramic ring 13, and stiffener 15, wherein a plurality of wires 16 are used to electrically connect a plurality of probes 120 to the stiffener 15 (also called upper power board 15), and an upper cover plate 17 is used to cover the wires 16 for a protection purpose. As shown in FIG. 1, the probes 120 are probe structures on the test fixture 10 for detecting IC components, and the substrate 14 (i.e. main-body plate 14) is formed with a central opening for receiving the probes 120. The foregoing elements are designed and processed by mechanically drilling, installing with each other, adhering with glue, and finely adjusting locations of the wires 16 and the probes 120, so as to finish the probe structures of the test fixture 10, i.e. the test probe of the present invention.

Referring now to FIG. 2, a partially enlarged view of a nano-film on a probe tip of the test probe on a test fixture is illustrated, as shown in FIG. 1. After this type of the probes 120 is coated with a nano-film 122 of conducting polymer, the probes 120 are still coplanar in comparison with other uncoated probes on the original test fixture 10. Because the thickness of the nano-film 122 is only about 1-20 nm, the size of the probes 120 is not apparently increased and the test quality of high-frequency probing is not affected. According to the preferred embodiment of the present invention, the structure of the probes 122, as shown in the partially enlarged view of FIG. 2, is not limited to the structure of the test fixture 10. In the present invention, only if the probe tip surface of the probes 122 on the test fixture 10 is coated with the nano-film 122 of conducting polymer, the probes 122 can provide the effect of the present invention.

In the present invention, the substrate 14 can be preferably selected from a printed circuit board or a silicon substrate. The material of the probes 120 on the test fixture 10 can be preferably selected from various electro-conductive metal or alloy. The foregoing alloy of the probes 120 and metal film thereon can be preferably selected from Be—Cu alloy coated with Au layer.

Furthermore, during transmitting signals, the probes 120 of the test fixture 10 are used to transmit signals. Because the probes 120 coated with the nano-film 122 of conducting polymer has the no-clean property, the probes 120 can be easily in contact with a correct tested location of a to-be-tested die without being wetted with foreign matter or impurity. Thus, the test probe of the present invention can transmit signals without generating noise signals, so as to enhance the transmission precision and improve the test stability.

In addition, in the present invention, the nano-film 122 of the probes 120 on the test fixture 10 is directly coated on the probe tip surface of the probes 120 by an evaporated and chemical plating process, so that the length of the nano-film 122 on the probes 120 can be controlled by a precision plating fixture. In the preferred embodiment, the precision plating fixture can be easily designed according to simple parameters, such as the size of the substrate (such as printed circuit board or silicon substrate) and the relative pitch of the probes 120. Thus, in the present invention, it is unnecessary to change the original structure of the test fixture 10 before finishing an advance process of forming the nano-film 122 of the probes 120. Meanwhile, in the present invention, the coplanarity of the probes 120 of the test fixture 10 will not be changed by the nano-film process. As a result, the yield and output quantity of the nano-film process can be apparently enhanced, while the time and cost of the entire manufacture process can be also lowered.

As described above, according to the test probe provided by the present invention, the nano-film 122 is formed on the probes 120 of the test fixture 10, so as to be advantageous to increase the integration density and the pin amount, and shorten the pin pitch. Meanwhile, the nano-film 122 of the probes 120 of the present invention is manufactured by the precision plating fixture and related process technologies, so that the manufacture cost of the nano-film 122 of the probes 120 on the test fixture 10 can be lowered and the yield thereof can be enhanced.

The present invention provides a test probe, wherein a plurality of probes 122 mounted on the test fixture 10 are mainly applied to the probing test for wafer and integrated circuit (IC) components of semiconductor industry or display industry. When traditional probes are used to carry out the probing test, the probe tip of the probes may be wetted with solder from the pads of a to-be-tested die. To solve the problem, a probe tip surface of the probes 120 in the present invention is coated with the nano-film 122 of conducting polymer for preventing from generating excessive attraction force between the probes 120 and the to-be-tested die or integrated circuit (IC) components, so that the probes 120 can provide excellent no-clean property. As a result, the cleaning frequency of the probes 120 can be lowered, the utility rate of test machines can be enhanced, and the test yield of the dies can be increased, so as to reduce the entire test cost. Thus, due to the nano-film 122 of conducting polymer, the test probe made of metal material can provide the same electro-conductivity as a traditional test probe by only plating a gold layer of one fifth of original thickness, so that the cost of whole probe material can be reduced.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A test probe, comprising:
a plurality of probes made of metal material and installed on a test fixture; and
a nano-film of conducting polymer coated on the probes.

2. The test probe of claim 1, wherein the nano-film of conducting polymer is conducting polymer having a no-clean property.

3. The test probe of claim 2, wherein the conducting polymer is selected from the group consisting of polypyrrole, polyparaphenylene, polythiophene, polyaniline, combination thereof, and derivative thereof.

4. The test probe of claim 1, wherein the thickness of the nano-film of conducting polymer is about 1-20 nm.

5. The test probe of claim 1, wherein the thickness of the nano-film of conducting polymer is about 1-5 nm.

6. The test probe of claim 1, wherein the metal material is selected from the group consisting of nickel, gold, copper, tungsten, rhenium, titanium, beryllium, stainless steel, electro-conductive metal, and alloy thereof.

7. The test probe of claim 6, wherein the alloy is rhenium-tungsten alloy or beryllium-copper alloy.

8. The test probe of claim 1, wherein each of the probes is coated with a metal film, and the nano-film is formed on the metal film.

9. The test probe of claim 8, wherein the metal film is made of gold or nickel.

10. The test probe of claim 8, wherein the thickness of the metal film is about 0.4-20 μm.

11. The test probe of claim 1, wherein the operation mode of the probes is unidirectional motion or bi-directional motion.

12. The test probe of claim 1, wherein each of the probes is selected from a metal micro-spring, a metal pin, a single tip pin, or a dual tip pin.

13. The test probe of claim 1, wherein the nano-film of conducting polymer is coated on each of the probes by a chemical plating process.

14. The test probe of claim 1, wherein the nano-film of conducting polymer is coated on a probe tip surface of each of the probes.
